(19) United States
(12) Patent Application Publication
(10) Pub. No.: US 2023/0212082 A1
(43) Pub. Date: Jul. 6, 2023

(54) PLASMA RESISTANT CERAMIC BODY FORMED FROM MULTIPLE PIECES

(71) Applicant: Heraeus Conamic North America LLC, CHANDLER, AZ (US)

(72) Inventors: Luke WALKER, Chandler, AZ (US); Matthew Joseph DONELON, Chandler, AZ (US); Sudip KOIRALA, Chandler, AZ (US)

(21) Appl. No.: 17/999,499

(22) PCT Filed: May 25, 2021
(86) PCT No.: PCT/US2021/033964

§ 371 Date: Nov. 21, 2022

Related U.S. Application Data
(60) Provisional application No. 63/029,868, filed on May 26, 2020.

(51) Int. Cl. C04B 37/00; C03C 10/00; C03C 4/20; C03C 8/02; B32B 5/16; B32B 37/06; B32B 7/12; B32B 9/00; B32B 9/04; B32B 7/027

(52) U.S. Cl. CPC C04B 37/003; C03C 10/00; C03C 4/20; C03C 8/02; B32B 5/16; B32B 37/06; B32B 7/12; B32B 9/005; B32B 9/048; B32B 7/027; C04B 2237/10; C04B 2237/343; C04B 2237/60; C04B 2237/708; C03C 2209/00; C03C 2204/00; H01L 21/6833

(57) ABSTRACT

Disclosed is a joined ceramic body comprising a first ceramic portion comprising a first ceramic, a second ceramic portion comprising a second ceramic, and a joining layer formed between the first ceramic portion and the second ceramic portion. The joining layer has a bond thickness of from 0.5 to 20 um and comprises silicon dioxide having a total impurity content of 20 ppm and less. A method of making the joined ceramic body and a joining material are also disclosed.

### FIELD

Embodiments of the disclosure relate to plasma resistant ceramic bodies formed from multiple pieces or portions for use as components in plasma etch or deposition chambers. The ceramic portions are joined or bonded to form a joined ceramic body using a plasma resistant glass or glass ceramic joining material. Moreover, embodiments of the present disclosure further provide a process for making the joined ceramic body and a plasma resistant ceramic component from the body.

### BACKGROUND

This section discloses subject matter related to the disclosed embodiments. There is no intention, either expressed or implied, that the background art discussed in this section legally constitutes prior art.

Glass is an amorphous solid and as such has no crystalline structure. A glass ceramic is made by first forming a glass and thereafter at least partially crystallizing the glass through careful control of thermal processing and cooling rates. This results in a glass ceramic material with a microstructure having crystalline regions surrounded by a glassy, amorphous matrix. The glassy matrix fills in voids and porosity which may otherwise be present in ceramic materials. Properties of the glass ceramic material may be adjusted according to composition and processing to achieve unique properties differing from those of glasses or ceramic materials.

During processing of semiconductor substrates, plasmas are typically used to remove materials on the chamber walls and substrates. The plasma conditions create a highly corrosive and erosive environment and expose the walls and components of the chamber to significant ion bombardment and chemical corrosion. This ion bombardment, combined with plasma chemistries and/or etch by-products, can produce significant surface roughening, erosion, corrosion and corrosion-erosion of the plasma-exposed surfaces of the processing chamber. As a result, the surface materials are removed by physical and/or chemical attack. This attack causes problems including short part lifetimes which lead to extended tool downtime, increased consumable costs, particulate contamination, on-wafer transition metal contamination and process drift.

Because of this erosive and corrosive nature of the plasma environment in such reactors, there is a need to minimize particle and/or metal contamination. Accordingly, it is desirable for component and bonding materials designed for fabrication of such equipment, including consumables and other parts, to have suitably high erosion and corrosion resistance. In keeping with this, those plasma chamber components and bonding or joining materials which have very high purity may provide a uniformly corrosion resistant surface low in impurities which may prevent corrosion and erosion during use. Such plasma chamber component parts have been formed from exemplary etch resistant materials, without limitation, as aluminum oxide, yttrium oxide, one or more forms of yttrium aluminum oxide, and aluminum nitride, that provide resistance to corrosion and erosion in plasma environments. These exemplary etch resistant bodies are disclosed in U.S. provisional patent application No. 62/829,720 entitled “controlled porosity yttrium oxide for etch applications” and U.S. provisional patent application No. 62/936,821 entitled “ceramic sintered body for corrosion resistant components” both of which are incorporated by reference herein in their entirety.

Typical glasses used in various electronics applications suffer from poor performance in halogen based plasma applications and/or high levels of alkali and alkaline earth elements, as well as borosilicate compounds making them unusable in applications where high purity is required. Further, the presence of boron in many glass compositions may be incompatible with semiconductor device manufacturing processes.

Plasma processing chambers have been designed to include parts such as disks, showerheads or windows, nozzles, chamber liners, various rings such as focus rings and protective rings, and cylinders that confine the plasma over the wafer being processed.

In order to meet the ongoing drive towards finer feature and node size, chamber components used in processing semiconductor substrates are required to have greater functionality, necessitating more complex structures. These structures may have multiple layers, embedded elements, partial or patterned layers of different materials combined into a single body or component. In order to fabricate these higher complexity structures, bonding or joining of multiple, etch resistant members may be required to form such components as wafer support assemblies, for example chucks or electrostatic chucks (ESC), RF or dielectric windows, injectors or nozzles having multiple openings for different process gases, process or other rings with embedded wires, mesh or other elements providing electrical functionality, among other components. Use of an array of materials bonded in various configurations poses issue due to the differing material properties. As example, mechanical properties of the joining material, such as the coefficient of thermal expansion (CTE), must be compatible with that of the ceramic member selected for use to avoid cracking and/or delamination from thermal excursions produced during use in semiconductor fabrication. Additionally, the bonding process often requires pressures on the order of 0.15 MPa and greater, for example up to 1.4 MPa, in order to ensure sufficient bonding between pieces. Further, the joining or bonding materials applied between the ceramic members are continuously attacked by the plasma in the same manner as the ceramic members and consequently erode, corrode or accumulate contaminants and polymer build-up and therefore are subject to the same etch resistance requirements as the ceramic members themselves. Thus, chamber component resistance to corrosion and erosion in halogen plasma applications, as well as the useful life of these components, may be limited by the bonding materials selected for use. There is an ongoing effort to improve the plasma resistance performance of chamber components for etch and deposition semiconductor processes, in particular those components made of multiple pieces to accommodate more stringent design requirements as necessitated by state of the art semiconductor processing chambers. Use of the materials and methods disclosed herein will provide performance improvements over the known art.

As such, there is a need for multiple piece, corrosion and erosion resistant ceramic bodies joined by corrosion and erosion resistant glass or glass ceramic materials.

### SUMMARY

Starting from the aforementioned related art, these and other needs are addressed by the various embodiments, aspects and configurations as disclosed herein:

/1/ A joined ceramic body comprising a first ceramic portion comprising a first ceramic, a second ceramic portion comprising a second ceramic, a joining layer formed between the first ceramic portion and the second ceramic portion, wherein the joining layer has a bond thickness of between 0.5 and 20 um and comprises silicon dioxide having a total impurity content of 20 ppm and less relative to a mass of the joining layer.

/2/ The joined ceramic body of claim 1 wherein the joining layer comprises an amorphous glassy phase having a total impurity content of 10 ppm and less relative to a mass of the joining layer.

/3/ The joined ceramic body of any one of the preceding claim 1 or 2 wherein the joining layer comprises a glass ceramic comprising an amorphous glassy phase and at least one crystalline ceramic phase.

/4/ The joined ceramic body of any one of the preceding claims 1 to 3 wherein the joining layer comprises at least one crystalline ceramic phase having crystallinity in an amount of from 5% to 99% by volume of the joining layer.

/5/ The joined ceramic body of any one of the preceding claims 1 to 4 wherein the joining layer comprises at least one crystalline ceramic phase having crystallinity in an amount of from 5% to 90% by volume of the joining layer.

/6/ The joined ceramic body of any one of the preceding claims 1 to 5 wherein the joining layer comprises at least one crystalline ceramic phase having crystallinity in an amount of from 5% to 70% by volume of the joining layer.

/7/ The joined ceramic body of any one of the preceding claims 1 to 6 wherein the joining layer comprises at least one crystalline ceramic phase having crystallinity in an amount of from 10% to 60% by volume of the joining layer.

/8/ The joined ceramic body of any one of the preceding claims 1 to 7 wherein the joining layer comprises at least one crystalline ceramic phase having crystallinity in an amount of from 10% to 50% by volume of the joining layer.

/9/ The joined ceramic body of any one of the preceding claims 1 to 8 wherein the at least one crystalline ceramic phase comprises at least one selected from the group consisting of mullite, alumina, Y2Si2O7, Y2SiO5 and Y3Al5O12 (yttrium aluminum garnet).

/10/ The joined ceramic body of any one of the preceding claims 1 to 9 wherein the Y3Al5O12 (yttrium aluminum garnet) is polycrystalline.

/11/ The joined ceramic body of any one of the preceding claims 1 to 10 wherein the joining layer has a total impurity content of 10 ppm and less relative to a mass of the joining layer.

/12/ The joined ceramic body of any one of the preceding claims 1 to 11 wherein the joining layer has a total impurity content of 5 ppm and less relative to a mass of the joining layer.

/13/ The joined ceramic body of any one of the preceding claims 1 to 12 wherein the joining layer has a total purity of 99.99% and higher relative to 100% purity.

/14/ The joined ceramic body of any one of the preceding claims 1 to 13 wherein the joining layer has a total purity of 99.995% and higher relative to 100% purity.

/15/ The joined ceramic body of any one of the preceding claims 1 to 14 wherein the joining layer has a total purity of 99.999% and higher relative to 100% purity.

/16/ The joined ceramic body of any one of the preceding claims 1 to 15 wherein the joining layer has a total alkali or alkali earth element content of 5 ppm and less relative to a mass of the joining layer.

/17/ The joined ceramic body of any one of the preceding claims 1 to 16 wherein the joining layer has a bond thickness of from 1 to 15 um.

/18/ The joined ceramic body of any one of the preceding claims 1 to 17 wherein the joining layer has a bond thickness of from 3 to 10 um.

/19/ The joined ceramic body of any one of the preceding claims 1 to 18 wherein the joining layer has a bond thickness of from 4 to 8 um.

/20/ The joined ceramic body of any one of the preceding claims 1 to 19 wherein the joining layer further comprises a rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof having a purity of 99.99% and higher relative to 100% purity of the joining layer.

/21/ The joined ceramic body of any one of the preceding claims 1 to 20 wherein the joining layer further comprises an element selected from the group consisting of Y, La, Ce, Pr, Nd, Pm, Sm, Eu, Gd, Tb, Dy, Ho, Er, Tm, Yb and Lu and combinations thereof.

/22/ The joined ceramic body of any one of the preceding claims 1 to 21 wherein the first and second ceramic portions comprises the same ceramic.

/23/ The joined ceramic body of any one of the preceding claims 1 to 22 wherein the first and second ceramic comprises different ceramics.

/24/ The joined ceramic body of any one of the preceding claims 1 to 23 wherein each of the first and second ceramic portions are selected from the group consisting of aluminum oxide, yttrium oxide, aluminum nitride, yttrium aluminum garnet (YAG; Y₃Al₅O₁₂), silicon carbide, quartz, mullite, SiAlON materials, and combinations thereof.

/25/ The joined ceramic body of any one of the preceding claims 1 to 24 wherein the first and second ceramic portions are aluminum oxide.

/26/ The joined ceramic body of any one of the preceding claims 1 to 25 wherein the joining layer has a coefficient of thermal expansion (CTE) of from 0 to 10% of each of the first and second ceramic portions.

/27/ The joined ceramic body of any one of the preceding claims 1 to 26 wherein the joining layer has a coefficient of thermal expansion (CTE) of from 0 to 5% of each of the first and second ceramic portions.

/28/ The joined ceramic body of any one of the preceding claims 1 to 27 wherein the first and second ceramic portions have a purity of 99.99% and higher relative to 100% purity.

/29/ The joined ceramic body of any one of the preceding claims 1 to 28 wherein the first and second ceramic portions have a purity of 99.995% and higher relative to 100% purity.

/30/ The joined ceramic body of any one of the preceding claims 1 to 29 having a purity of 99.99% and higher relative to 100% purity.

/31/ A method of making a joined ceramic body, the method comprising disposing a powder of silicon dioxide between surfaces of a first ceramic portion and a second ceramic portion to form a ceramic body assembly, increasing the temperature of the ceramic body assembly to a sintering temperature sufficient to join first and second ceramic portions to form the joined ceramic body, and lowering the temperature of the joined ceramic body wherein the silicon dioxide has a specific surface area of from 25 m²/g to 50 m²/g as measured according to ASTM C1274, and a purity of 99.999% and higher relative to 100% purity, characterized in that the process is carried out under condition to prepare a joined ceramic body having characteristics as disclosed in any one of the preceding claims.

/32/ The method according to claim 31 wherein step a. further comprises a powder of aluminum oxide wherein the aluminum oxide has a purity of 99.99% and higher.

/33/ The method according to any one of claim 31 or 32 wherein step a. further comprises a powder of at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof having a purity of 99.99% and higher.

/34/ The method according to any one of claims 31 to 33 wherein the sintering temperature of step b. is between 1100 and 1500° C.

/35/ The method according to any one of claims 31 to 34 wherein step a. further comprises a powder of yttrium oxide having a purity of 99.995% and greater relative to 100% purity.

/36/ The method according to any one of claims 31 to 35 further comprising the step of machining the joined ceramic body to create a joined ceramic body component for use in a semiconductor processing chamber.

/37/ The method according to any one of claims 31 to 36 wherein the joined ceramic body component is selected from the group consisting of: a dielectric window or RF window, a ring, a nozzle or a gas injector, a shower head, a gas distribution plate, an etch chamber liner, a plasma source adapter, a gas inlet adapter, a diffuser, an electronic wafer chuck, a chuck, a puck, an ion suppressor element, a faceplate, and/or a protective ring in etch chambers.

/38/ A joined ceramic body for production of semiconductor chamber components made by the process of any one of claims 31 to 37.

/39/ A joined ceramic body according to anyone of claims 31 to 38 having a size of from 100 mm to 622 mm, preferably from 200 to 622 mm, preferably from 300 to 622 mm, preferably from 400 to 622 mm, more preferably from 450 to 622 mm, more preferably from 500 to 622 mm, more preferably 550 to 622 mm, each with regard to the longest extension of the ceramic body.

/40/ A plasma resistant composition comprising silicon dioxide having a particle size of between 30 and 200 nm and a specific surface area as measured by BET methods of between 25 m2/g and 50 m2/g, aluminum oxide, and at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof, and a suspension medium, wherein the plasma resistant composition comprises a paste.

/41/ The plasma resistant composition of claim 40 wherein the silicon dioxide has a total purity of at least 99.999% and higher relative to 100% purity.

/42/ The plasma resistant composition of any one of claim 40 or 41 wherein the at least one rare earth oxide comprises yttrium oxide having a purity of 99.99% and greater relative to 100% purity.

/43/ The plasma resistant composition of any one of claims 40 to 42 having a total purity of at least 99.995% and greater relative to 100% purity.

/44/ The plasma resistant composition of any one of claims 40 to 43 wherein the suspension medium comprises a liquid selected from the group consisting of water, ethanol, isopropanol, glycerol, and combinations thereof.

/45/ The plasma resistant composition of any one of claims 40 to 44 having a maximum particle size (d100) of between 4 and 6 microns.

/46/ The plasma resistant composition of any one of claims 40 to 45 wherein the aluminum oxide has a purity of 99.99% and higher relative to 100% purity.

/47/ The plasma resistant composition of any one of claims 40 to 46 wherein the at least one rare earth oxide selected from the group consisting of Y₂O₃, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof has a purity of 99.99% and higher.

/48/ The plasma resistant composition of any one of claims 40 to 47 wherein the silicon dioxide is present in an amount of from 25 to 60% by weight, and the balance comprises a mixture of aluminum oxide in an amount of from 25 to 50% by weight, and at least one rare earth oxide in an amount of from 50 to 75% by weight.

/49/ The plasma resistant composition of claim 48 wherein the rare earth oxide comprises yttrium oxide.

/50/ The plasma resistant composition of claim 49 used according to the method of any one of claims 31 to 39.

/51/ A joined ceramic body comprising first and second ceramic portions of aluminum oxide; a joining layer formed between the first and second ceramic portions having a bond thickness of from 0.5 to 20 um, wherein the first and second ceramic portions have a purity of 99.99% and higher, and the joining layer comprises a glass ceramic comprising an amorphous glassy phase and at least one crystalline ceramic phase wherein the joining layer has a total impurity content of 20 ppm and less relative to a mass of the joining layer.

/52/ A joined ceramic body comprising first and second ceramic portions of yttrium aluminum oxide garnet (YAG, Y3Al5O12) and a joining layer formed between the first and second ceramic portions, wherein the first and second ceramic portions have a purity of 99.99% and higher, wherein the joining layer comprises a glass ceramic comprising an amorphous glassy phase and at least one crystalline ceramic phase selected from the group consisting of yttrium aluminum garnet (YAG; Y3Al5O12), yttrium aluminum monoclinic (YAM, Y4Al2O9), and yttrium aluminum perovskite (YAP, YAlO3), wherein the joining layer has a total impurity content of 20 ppm and less relative to a mass of the joining layer and a bond thickness of from 0.5 to 20 um.

/53/ A joined ceramic body comprising first and second ceramic portions of aluminum oxide and a joining layer formed between the first and second ceramic portions, wherein the first and second ceramic portions have a purity of 99.99% and higher and the joining layer comprises a glass ceramic comprising an amorphous glassy phase and at least one crystalline ceramic phase wherein the at least one crystalline ceramic phase is selected from the group consisting of mullite, alumina, Y2Si2O7, Y2SiO5, and Y3Al5O12 (yttrium aluminum garnet), wherein the joining layer has a total impurity content of 20 ppm and less and a bond thickness of between 0.5 and 20 um.

/54/ A joined ceramic body comprising first and second ceramic portions of yttrium aluminum oxide garnet (YAG, Y3Al5O12), a joining layer formed between the first and second ceramic portions and the first and second ceramic portions have a purity of 99.99% and higher, and the joining layer comprises a glass ceramic comprising an amorphous glassy phase and at least one crystalline ceramic phase selected from the group consisting of mullite, alumina, Y2Si2O7, Y2SiO5, and Y3Al5O12 (yttrium aluminum garnet), and the joining layer has a total impurity content of 20 ppm and less relative to a mass of the joining layer and the joining layer has a bond thickness of from 0.5 to 20 um.

### BRIEF DESCRIPTION OF THE DRAWINGS

FIG. 1 depicts an embodiment of a joined ceramic body in accordance with the disclosure.

FIG. 2 depicts an embodiment of a joined ceramic body not in accordance with the disclosure.

FIG. 3 shows differential scanning calorimetry (DSC) results for a glass ceramic joining material as disclosed herein.

FIG. 4 illustrates a semiconductor processing system according to embodiments of the present technology.

FIG. 5 illustrates a wafer support assembly having chamber components of a chuck or electronic wafer chuck or electrostatic chuck (ESC) and a cover ring.

FIGS. 6A and 6B show a plan view and a detail cross section view of various rings used in semiconductor processing systems as disclosed herein.

FIG. 7 shows representative cross section views which may be applied to embodiments depicted in FIGS. 4, 5 and 6 as well as other multiple piece ceramic bodies or components as disclosed herein.

FIG. 8 is the ternary yttria-silica-alumina phase diagram illustrating the crystalline phases formed, and the proportions and temperatures necessary to form them.

### DETAILED DESCRIPTION

Reference will now be made in detail to specific embodiments. Examples of the specific embodiments are illustrated in the accompanying drawings. While the disclosure will be described in conjunction with these specific implementations, it will be understood that it is not intended to limit the disclosure to such specific embodiments. On the contrary, it is intended to cover alternatives, modifications, and equivalents as may be included within the spirit and scope as defined by the appended claims. In the following description, numerous specific details are set forth in order to provide a thorough understanding of the disclosed embodiments. The present disclosure may be practiced without some or all of these specific details.

When the word “about” is used herein, the nominal value disclosed has an associated variation of +/−10%.

Disclosed herein are materials and methods useful for fabrication of chamber parts for semiconductor and/or microelectromechanical (MEMs) processing systems. Specifically, the materials and methods relate to a joining material useful for bonding separate structures together to fabricate a ceramic body component which provides enhanced resistance to halogen based process gases, and more specifically to process gases containing fluorine, as used in etch and/or deposition semiconductor processes.

These components made of joined structures may be chamber liners, RF or microwave windows, showerheads and/or gas distribution assemblies, focus, shield or clamping rings (and other ring designs as known to those skilled in the art), gas injectors or nozzles, wafer chucks and/or electronic wafer chucks by way of example and not by way of limitation. The joining material as disclosed, method of making the joining material and use in making plasma resistant ceramic body components will enable fabrication of a range of components having greater structural complexity and finer feature size useful for fabrication of chamber components to meet design requirements for next generation technologies. As example, use of the corrosion and erosion resistant joining material disclosed herein provides the ability to bond structural members together while maintaining low particle generation, reduced contamination at the wafer scale, and extended component assembly lifetimes as necessary for use in semiconductor and MEMS processing applications. The materials and methods as disclosed herein provide a joined ceramic body and/or component resistant to corrosion and erosion of very high purity such that particles which may be released into the chamber may not be detrimental to semiconductor processing.

In an embodiment, disclosed herein is a joined ceramic body comprising a first ceramic portion comprising a first ceramic, a second ceramic portion comprising a second ceramic, and a joining layer formed between the first ceramic portion and the second ceramic portion. The joining layer may have a thickness of between 0.1 and 20 um and comprises silicon dioxide having a total impurity content of 20 ppm and less.

The first and second ceramic portions may be selected from the same ceramic or different, dependent upon application specific requirements. In embodiments, first and second ceramic portions are selected from aluminum oxide, yttrium oxide, aluminum nitride, yttrium aluminum garnet (YAG; Y₃Al₅O₁₂), silicon carbide, mullite, quartz, SiAlON materials and combinations thereof. The materials selected for first and second ceramic portions may have suitably high corrosion and erosion resistance, material properties such as coefficient of thermal expansion, and purity acceptable for use as the joined ceramic body as disclosed. Specific combinations of joining layer and first and second ceramic portions are disclosed herein for fabrication of a joined ceramic body however embodiments of the joined ceramic body beyond those disclosed are also possible.

The joining layer may be comprised of silicon dioxide or combinations of silicon dioxide, aluminum oxide, and at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3. In preferred embodiments, the rare earth oxide comprises yttrium oxide. The joining layer made of silicon dioxide may have very high purity, for example having a total purity of greater than 99.999%, preferably greater than 99.9995%, preferably 99.9999%, with respect to 100% pure silicon dioxide, corresponding to impurity levels of 10 ppm, 5 ppm and 1 ppm, respectively. Use of high purity silicon dioxide as disclosed provides a very low (5 ppm in total) alkali and/or alkaline earth joining layer which enhances resistance to halogen-based plasmas and reduces surface roughening and particle generation. The alkali and/or alkaline earth elements as disclosed herein comprise Li, Na, K, Mg, Ca and Sr in total combined amounts of not greater than 5 ppm by weight of the joining layer. Mg in the form of MgO is present in the joining materials in an amount of 2 ppm and less relative to a total mass of the joining material. For other embodiments as disclosed herein, the joining layer may be formed from silicon dioxide, aluminum oxide, and at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations of these whereby the joining layer has a purity of 99.995% and greater, preferably 99.998% and greater, preferably 99.999% and greater. The joining layer as disclosed may include an element selected from the group consisting of Y, La, Ce, Pr, Nd, Pm, Sm, Eu, Gd, Tb, Dy, Ho, Er, Tm, Yb and Lu and combinations thereof.

In some embodiments, the joining layer may comprise an amorphous, high purity (>99.999%) glass, and in alternate embodiments it may comprise a high purity (>99.99%) glass ceramic comprising an amorphous, glassy phase or matrix, and a crystalline phase dispersed in the matrix, wherein the crystalline ceramic phase forms in an amount between 5% and 99% by volume of the joining layer, preferably between 5% and 90% by volume, preferably between 5% and 70% by volume, preferably between 10% and 60% by volume, preferably between 10% and 50% by volume, each by volume of the joining layer. Either or both the glassy phase and glass ceramic phases (comprising a glassy phase and at least one crystalline ceramic phase) of the joining layer may in embodiments comprise at least one of the elements selected from the group consisting of Y, La, Ce, Pr, Nd, Pm, Sm, Eu, Gd, Tb, Dy, Ho, Er, Tm, Yb and Lu and combinations thereof.

In embodiments, it may be beneficial to minimize the thickness of the joining layer which may provide enhanced mechanical strength and improved plasma resistance. Disclosed is a joined ceramic body having a joining layer with a thickness of from 0.1 to 20 um, preferably from 0.1 to 15 um, preferably from 0.1 to 10 um, preferably from 0.1 to 5 um, preferably from 0.1 to 3 um, preferably from 1 to 8 um, preferably from 3 to 5 um.

In embodiments as disclosed, it may be beneficial to select a glass ceramic joining layer having a coefficient of thermal expansion (CTE) the same as, or very close to, that of the first and/or second ceramic portions to minimize stresses between the ceramic portions and/or the glass ceramic joining layer upon heating, cooling and during use. This may prevent delamination or cracking of the ceramic body and/or the glass ceramic joining layer. The coefficient of thermal expansion of the glass ceramic joining layer may be adjusted for compatibility with that of the ceramic portions by varying the relative amounts of silicon dioxide, aluminum oxide, and at least one rare earth oxide as disclosed herein, for example such as yttrium oxide. The glass ceramic joining layer as disclosed may have a CTE the same as that of the ceramic portions, i.e. no difference, and between 0 to 5% or from 0 to 10% of the ceramic portions across a temperature range from about 200° C. to 1400° C.

Compositions of the glass ceramic joining material can be selected to CTE match to, for example, 10% or less of the substrate by adjustment of the composition (of yttria, alumina and silica). Silica has a CTE of about 0.5 to 1×10−6/° C., YAG has a CTE of from 7 to 8×10−6/° C., and alumina has a CTE of from 4 to 5×10−6/° C. and by varying their relative amounts, the CTE of the glass ceramic joining material may be modified.

Disclosed is a method of making a joined ceramic body. The method disclosed herein comprises the steps of:
a. disposing a powder of silicon dioxide between surfaces of a first ceramic portion and a second ceramic portion to form a ceramic body assembly;
b. increasing the temperature of the ceramic body assembly to a sintering temperature of the powder of silicon dioxide sufficient to join first and second ceramic portions to form the joined ceramic body; and
c. lowering the temperature of the joined ceramic body,
   wherein the silicon dioxide has a specific surface area as measured by BET methods of at least 25 m2/g and a purity of 99.999% and higher characterized in that the process is carried out under condition to prepare a joined ceramic body having characteristics as disclosed in any one of the preceding claims. The terms “surface area” and “specific surface area” are used interchangeably herein, and refer to a surface area as expressed in m2/g. The method disclosed herein comprises step a disposing a powder of silicon dioxide between surfaces of a first ceramic portion and a second ceramic portion to form a ceramic body assembly. The powder of silicon dioxide may have a specific surface area as measured by BET methods as known in the art of 25 m2/g and higher, preferably 30 m2/g and higher, preferably between 25 to 50 m2/g, preferably between 25 to 40 m2/g. Surface areas of the silicon dioxide exceeding about 60 m2/g and greater may adversely impact reaction kinetics. Specific surface areas (SSA) for the starting powders were measured using a Horiba BET Surface Area Analyzer model SA-9601 capable of measuring across a specific surface area of 0.01 to 2000 m²/g with an accuracy of 10% and less for most samples.

It is preferred, though not required, that the silicon dioxide is a nano powder, having an average particle size as measured by laser particle size measurement methods of between 20 to 200 nm, between 20 to 150 nm, between 20 to 100 nm, between 40 to 200, between 70 to 200 nm, between 100 to 200 nm, preferably an average particle size of between 30 to 90 nm. Particle sizes for the starting powders were measured using a Horiba model LA-960 Laser Scattering Particle Size Distribution Analyzer capable of measuring particle size from 10 nm to 5 mm. The fine particle size associated with silicon dioxide nano powders may result in agglomerates which as defined herein are clusters of loosely bound particles which may be broken down with application of shear or grinding forces applied during mixing or milling processes. The silicon dioxide powder may have an average agglomerate size of between 0.75 and 3 um, between 0.75 and 2.5 um, between 0.75 and 2 um, preferably between 1 and 2 um. The silicon dioxide powder may have a d90 agglomerate size of between 4 to 6 um, preferably between 4 to 5.5 um, preferably between 4.5 to 5.5 um.

The silicon dioxide powder forming the joining layer is of very high purity, having a total purity of greater than 99.999%, preferably greater than 99.9995%, preferably 99.9999% and greater. These levels of purity correspond to total impurity levels of 10, 5 and 1 ppm, respectively. The total purity also includes alkali and alkaline earth elements as well as low melting temperature, volatile metals, which are detrimental to application as components in semiconductor processing chambers.

To achieve the lowered sintering temperatures as disclosed, the silicon dioxide may in embodiments be a nanopowder. A nanopowder as used herein is intended to mean a powder having a particle size of between 20 to 200 um in diameter and a specific surface area of 25 m2/g and higher. The high purity of the silicon dioxide also provides a joining layer having a very low (<5 ppm) of alkali and/or alkaline earth glass or glass ceramic composition with high join strength providing high resistance to halogen based plasmas. The silicon dioxide powder as disclosed herein further provides a very low (<5 ppm total) transition metal content (comprising Fe, Co and Ni) and comprises the alkali and/or alkaline earth elements of Li, Na, K, Sr, Mg and Ca in amounts of less than 2 ppm each, preferably less than 1 ppm each.

The combination of high purity, high surface area and fine particle size of the silicon dioxide provides enhanced reactivity, reducing joining temperatures and times without the requirement for applied pressure, although it may be used if desired. Use of highly pure silicon dioxide which is preferably a nanopowder having a very small particle size and high surface area reduces the activation energy necessary for sintering and thereby contributes to reduced sintering temperatures of the joining material, as described in Vipin Kant Singh (1977) “Studies on the Sintering of Silicon Dioxide”, Transactions of the Indian Ceramic Society, 36:1, 1-6, which is herein incorporated by reference. The activation energy as described therein may be calculated according to the Arrhenius Equation:

K=A exp(−Q/RT)

where K is a rate constant, Q is the activation energy, T the absolute temperature, R the universal gas constant and A another constant. Sintering temperatures according to the embodiments disclosed herein may be between 1100 to 1500° C., preferably between 1100 to 1400° C., preferably between 1100 to 1300° C., preferably between 1100 to 1200° C., preferably between 1200 to 1500° C. preferably between 1300 to 1500° C., preferably between 1400 to 1500° C., preferably between 1200 to 1400° C.

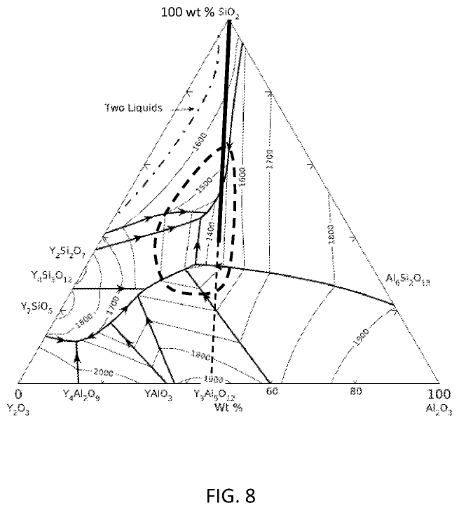

In embodiments, the silicon dioxide powder of step a further comprises a powder of aluminum oxide and a powder of a rare earth oxide, for example yttrium oxide, wherein the aluminum oxide and yttrium oxide and/or rare earth oxide each have a purity of 99.99% and higher. Without being bound by any particular theory, the dominant sintering mechanism for those high silica content (greater than 60% silica by weight and up to and including 100% silica) joining materials (also comprising alumina and yttria as disclosed herein) may be viscous phase sintering due to the highly reactive silica, combined with the viscous flow of the high silica content compositions to facilitate wetting of the ceramic portions. The high surface area of the silica nanopowders as disclosed increases the reactivity of the powders, and thereby reduces the sintering temperature, allowing for sintering of high silica compositions within the temperature range of the method as disclosed. Use of silica having lower surface area and larger particle sizes may require higher sintering temperatures, in excess of 1600° C. The compositional range for the joining material comprising high silica amounts is depicted as a bold line in the phase diagram of FIG. 8. FIG. 8 also depicts the liquidus temperatures at which compositions of yttria, silica and alumina may combine to form liquid phases. As such, some embodiments of the joining materials may comprise silica in an amount of from 60 to 100% by weight, and the balance comprising a mixture of alumina in amounts of from 25 to 50% by weight, and yttria in amounts of from 50 to 75% by weight. In some embodiments, across this compositional range, the crystalline ceramic phases of Y2Si2O7 and mullite (3Al2O3-2SiO2) may form, dispersed in a glassy, silica rich phase or matrix. In alternate embodiments, across this compositional range, the starting crystalline materials of yttria and alumina may be dispersed in a glassy, silica rich phase or matrix. The yttria, silica, alumina phase diagram according to H. Mao, M. Selleby and M. Fabrichnaya (2008) provides guidance as to the crystalline phases formed upon cooling below the eutectic point of the compositional ranges of the powder mixtures and the plasma resistant compositions as disclosed herein. The eutectic point as known to those skilled in the art is defined as the point on a phase diagram where the maximum number of allowable phases are in equilibrium.

As known in the art, the d50 particle size is defined as the median particle size and represents the value where half of the population resides above this point, and half resides below this point. Similarly, 90 percent of the distribution lies below the d90 particle size, and 10 percent of the population lies below the d10.

The d10 particle size of the yttrium oxide powder used as a starting material according to one embodiment of the present invention is preferably from 1 to 7 μm, preferably from 1 to 6 μm, preferably from 1 to 5 μm, preferably from 2 to 7 μm, preferably from 3 to 7 μm, preferably from 4 to 7 μm, preferably from 5 to 7 μm.

The d50 particle size of the yttrium oxide powder used as a starting material according to one embodiment of the present invention is preferably from 3 to 11 μm, preferably from 3 to 9.5 μm, preferably from 3 to 8.5 μm, preferably from 3 to 7.5 μm, preferably from 4 to 11 μm, preferably from 5 to 11 μm, preferably from 6 to 11 μm, preferably from 7 to 11 μm.

The d90 particle size of the yttrium oxide powder used as a starting material according to one embodiment of the present invention is preferably from 6 to 20 μm, preferably from 6 to 18 μm, preferably from 6 to 16 μm, preferably from 8 to 20 μm, preferably from 10 to 20 μm, preferably from 15 to 20 μm, preferably from 8 to 18 μm, preferably from 10 to 18 μm.

The yttrium oxide powder usually has a specific surface area (SSA) of from 1 to 12 m²/g, preferably from 1 to 9 m²/g, preferably from 1 to 6 m²/g, preferably from 1 to 4 m²/g, preferably from 2 to 9 m²/g, preferably from 2 to 6 m²/g, preferably from 2 to 4 m²/g.

The purity of the yttrium oxide starting material is preferably higher than 99.99%, preferably higher than 99.995%, preferably higher than 99.999%, more preferably higher than 99.9995%, and more preferably higher than 99.9999%. This corresponds to impurity levels of 100 ppm and less, preferably 50 ppm and less, preferably 25 ppm and less, preferably 10 ppm and less, more preferably about 1 ppm, preferably from 1 to 100 ppm, preferably from 1 to 50 ppm, preferably from 1 to 25 ppm, preferably from 1 to 10 ppm, preferably from 1 to 5 ppm, each relative to a total mass of the yttrium oxide starting material. The d10 particle size of the aluminum oxide powder used as a starting material according to one embodiment of the present invention is preferably from 0.05 to 4 μm, preferably from 0.05 to 3 μm, preferably from 0.05 to 2 μm, preferably from 0.05 to 1 μm, preferably from 0.05 to 0.75 μm, preferably from 0.05 to 0.5 μm, preferably from 0.2 to 4 μm, preferably from 0.2 to 3 μm, preferably from 0.2 to 2 μm, preferably from 0.2 to 1 μm, preferably from 0.4 to 4 μm, preferably from 0.4 to 3 μm, preferably from 0.4 to 2 μm, preferably from 0.4 to 1 μm, preferably from 0.75 to 2 μm, preferably from 0.75 to 3 μm, preferably from 1 to 3 μm, preferably from 2 to 3 μm.

The d50 particle size of the aluminum oxide powder used as a starting material according to one embodiment is usually from 0.15 to 8 μm, preferably from 0.15 to 5 μm, preferably from 0.15 to 3 μm, preferably from 0.15 to 1 μm, preferably from 0.15 to 0.5 μm, preferably from 1 to 8 μm, preferably from 1 to 6 μm, preferably from 1 to 4 μm, preferably from 2 to 6 μm, preferably from 3 to 8 μm, preferably from 4 to 8 μm, preferably from 5 to 8 μm, preferably from 3.5 to 6.5 μm.

The d90 particle size of the aluminum oxide powder used as a starting material according to one embodiment of the present invention is from 0.35 to 60 um, preferably from 0.35 to 10 um, preferably from 0.35 to 5 μm, preferably from 0.35 to 3 μm, preferably from 0.35 to 1 μm, preferably from 0.35 to 0.75 μm, preferably from 3 to 80 um, preferably from 3 to 60 μm, preferably from 3 to 40 μm, preferably from 3 to 20 μm, preferably from 10 to 60 μm, preferably from 10 to 40 μm, preferably from 10 to 30 μm, preferably from 10 to 20 μm, preferably from 30 to 60 μm, preferably from 15 to 60 μm, preferably from 40 to 60 μm, preferably from 6 to 15 μm.

The aluminum oxide powder usually has a specific surface area of from 3 to 18 m²/g, preferably from 3 to 16 m²/g, preferably from 3 to 14 m²/g, preferably from 3 to 12 m²/g, preferably from 3 to 10 m²/g, preferably from 3 to 6 m²/g, preferably from 6 to 18 m²/g, preferably from 6 to 14 m²/g, preferably from 8 to 18 m²/g, preferably from 10 to 18 m²/g, preferably from 8 to 10 m²/g, preferably from 4 to 9 m²/g, preferably from 5 to 10 m²/g, preferably from 6 to 8 m²/g.

The purity of the aluminum oxide starting material is typically higher than 99.99%, preferably higher than 99.995%, preferably higher than 99.999%, preferably higher than 99.9995%, as measured using ICPMS methods. Correspondingly, the total impurity content of the alumina powder may be 100 ppm and less, preferably 50 ppm and less, preferably 25 ppm and less preferably 10 ppm and less, more preferably 5 ppm and less, each relative to a total mass of the aluminum oxide starting material.

Compound oxide powder mixtures of more than one powder are hereinafter referred to as a joining material, comprising combinations of silicon dioxide as disclosed herein, aluminum oxide and at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof. In preferred embodiments, the rare earth oxide comprises yttrium oxide having the powder characteristics as disclosed herein.

The total purity also includes alkali and alkaline earth elements as well as low melting temperature, volatile metals, which are detrimental to application to semiconductor processing chambers.

In embodiments, step a of the method to form a joined ceramic body may further comprise providing powders of at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof wherein the rare earth oxides each have a purity of 99.99% and higher.

The rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations of these may have a surface area as measured by BET methods as known to those skilled in the art which may be at least 2 m2/g, preferably at least 4 m2/g, preferably at least 6 m2/g, from between 2 to 10 m2/gm, preferably between 4 m2/g to 8 m2/g.

The group of rare earth oxides as disclosed herein may have an average particle size distribution as measured using laser particle size measurement methods as known in the art of between 2 to 15 um, preferably between 3 to 10 um, preferably between 4 to 8 um.

The group of rare earth oxides as disclosed herein may have a total purity of greater than 99.99%, preferably greater than 99.995%, preferably greater than 99.999% with respect to 100% of the compound oxide purity. These levels of purity correspond to total impurity levels of 100, 50, and 10 ppm, respectively. The total purity also includes alkali and alkaline earth elements as well as low melting temperature, volatile metals, which are detrimental to application to semiconductor processing chambers.

The selection of the silicon dioxide and metal oxide powders and their relative amounts is made dependent upon the product specific application requirements, and the desired properties for the joining layer formed from the joining material during a sintering process as disclosed herein. Selection of joining materials is dependent upon the desired properties of plasma resistance and specific material properties such as the coefficient of thermal expansion. The examples disclosed herein use silicon dioxide (SiO2) and joining materials of combinations of silicon dioxide (SiO2), aluminum oxide (Al2O3), and a rare earth oxide for example yttrium oxide (Y2O3). The silicon dioxide powders are preferably nanopowders. However, any number of other rare earth oxides may be used in varying amounts. Rare earth oxides may be selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations of these as example, without limitation. The joining layer formed from the starting powders may be a glass or a glass ceramic. Dopants or additives may be incorporated into the joining layer for their specific desired properties provided therein. All starting powders (and rare earth oxides or dopants, where applicable) are of purity at least 99.99% and greater, and free of fluorides and oxyfluorides. Table 1 lists properties of compound oxide powders useful as joining materials for forming the joining layer as disclosed herein.

TABLE 1

| | Purity | Surface Area | Average Particle | d90 Particle |
|---|---|---|---|---|
| Oxide | (%) | (m2/g) | Size (um) | Size (um) |
| SiO2 | ≥99.999 | 25 to 50 | 0.75 to 3* | 4 to 6 |
| Al203 | ≥99.99 | 6 to 18 | 1 to 3 | 5 to 7 |
| Y2O3 | ≥99.999 | 2 to 9 | 2.5-5.5 | 7.5 to 9.5 |
| La2O3 | ≥99.999 | 4 to 12 | 1 to 3 | 6 to 8 |

*denotes average agglomerate size

Step a of the method further includes mixing, blending, milling or suspending the joining material in a suspension medium as necessary to prepare the joining material for step b. In embodiments, the joining material may be in the form of a powder mixture of silicon dioxide (which is preferably a nano powder), aluminum oxide, yttrium oxide and/or the aforementioned compound oxides. In alternate embodiments, the powder mixture may be in the form of a paste containing the aforementioned powders of the joining material and a suspending medium such as for example solvents of water, ethanol, isopropanol, glycerol, and combinations thereof to form a plasma resistant composition. Additional, optional dopants may be added to any of the aforementioned forms of the joining material and/or plasma resistant composition. The plasma resistant composition comprises a paste comprising between 10 and 50% by volume of the powder mixture, between 20 and 50% by volume of the powder mixture, preferably between 30 and 50% by volume of the powder mixture. Selection of one or more mixing methods and a suspension medium (if used) and the amount thereof is made dependent on the method selected for application of the joining material or plasma resistant composition to the surface of the ceramic portion/s. Methods for mixing, blending or milling are as disclosed following and may be used to combine the powders into a powder mixture. In order to combine the powders to form the joining material and/or plasma resistant composition, the disclosed powders may be mixed according to the processes of vertical (end over end) tumble mixing, high energy ball milling or jet milling, without limitation as known in the art. Ball milling and tumble mixing may be done dry or wet, in which case milling may be performed in a liquid medium such as solvent or aqueous based systems as previously mentioned, or simply using the powder mixture with or without milling media. Any of the aforementioned milling processes may use high purity media, such as aluminum oxide of purity 99.99% and/or 99.995%, to preserve the purity of the starting oxide powders, with a milling media loading by weight of from 20% to 80% of powder weight. The mixing processes as disclosed serve to maintain the purity of the joining material and/or the plasma resistant composition after mixing and may be repeated as needed for desired results. Preferable is a plasma resistant composition or joining material having a maximum particle size (d100) of from 4 to 6 um, preferably from 4 to 5 um, more preferably a maximum particle size of 4 um and less. As used herein, the plasma resistant composition may be comprised of the same or similar powders as the joining material, with the addition of a suspending medium as disclosed herein, to form a plasma resistant composition in the form of a paste. The plasma resistant composition as disclosed herein is one embodiment of the joining material.

Step a of the method further comprises disposing the silicon dioxide (or the plasma resistant composition or joining material as the case may be) between a first ceramic portion and a second ceramic portion to form a ceramic body assembly. The selected joining material (or plasma resistant composition) may be applied between surfaces of various ceramic substrates which are capable of withstanding the bonding temperatures as disclosed herein to form a glass or glass ceramic joining layer between the ceramic portions. Properties of the glass or glass ceramic joining layer may be determined by compositions of the selected joining materials and their characteristics, method of mixing prior to formation of the joining layer, thermal processing during sintering and cooling, among other techniques as known to those skilled in the art.

For the embodiments disclosed herein, the silicon dioxide powder (or joining material or plasma resistant composition as the case may be) may be applied to a surface of a first ceramic portion. Application of the joining material in powder form may be done by dusting or sprinkling the powder mixture comprising the joining material on a surface of the first ceramic portion. Application of the joining material or plasma resistant composition in a suspension medium (in amounts as needed to form a paste or slurry from the suspension medium and the powders) may be done by painting, spraying, dipping, spin coating, and screen printing, among others as known to those skilled in the art. Thereafter a surface of a second ceramic portion is brought into contact with the layer of joining material or plasma resistant composition to form the ceramic body assembly. The joining material or plasma resistant composition is applied over the surface of the substrate to be joined as disclosed above by way of example and not by way of limitation. The method of application must be compatible with the properties of the joining material or plasma resistant composition. Preferred embodiments utilize a paste or slurry to dispose the oxide powders between surface of the ceramic portions.

Ceramic portions may be selected from a variety of materials, such as Al2O3, SiAlON, SiC, Y2O3, yttrium aluminum garnet (YAG, Y₃Al₅O₁₂), mullite and combinations thereof. Selection of substrate materials may be done based upon resistance to halogen-based plasmas, mechanical strength, thermal conductivity, dielectric breakdown strength, CTE matching (within 0 to 10%) to the joining layer, and others. As a non-limiting example, the joining material may be placed between two similar materials varying in electrical characteristics, such as a ceramic portion of a first electrical resistivity, and a ceramic portion of a second electrical resistivity, to provide a high strength, plasma resistant bond between the two regions while maintaining the corrosion resistance provided by the aluminum oxide ceramic portions. The ceramic portions as disclosed herein may have a purity of at least 99.99% and greater, preferably 99.995% and greater, preferably 99.999% and greater. U.S. provisional patent application No. 62/829,720 entitled “controlled porosity yttrium oxide for etch applications” and U.S. provisional patent application No. 62/936,821 entitled “ceramic sintered body for corrosion resistant components” disclose purities of yttrium oxide and yttrium aluminum garnet (YAG) of from greater than 99.99% to 99.999% relative to 100% purity, both of which are incorporated by reference herein in their entirety. As one example, the following Table A provides purity of an exemplary powder mixture comprising yttria and alumina (batched in amounts to form the YAG phase, Y3Al5O12, upon sintering) in accordance with the joining materials of the present invention. Embodiments of the exemplary powder mixture for use according to the current disclosure may be mixed with from 25 wt % to 99 wt % of the high purity silica powders as disclosed herein.

TABLE A
Yttria-Alumina Powder Mixture (forming Y₃Al₅O₁₂)

| | Average | | Average |
|---|---|---|---|
| | Impurity | | Impurity |
| Element | (ppm) | Element | (ppm) |
| Li 6/7 | 0.0197 | Cd 111 | 0.1989 |
| Be 9 | 0.1808 | In 115 | <0.0035 |
| B 11 | <0.0007 | Sn 118 | 0.0798 |
| Na 23 * | 1.8755 | Sb 121 | 0.0297 |
| Mg 24 | <0.7 | Te 126, 8, 30 | <0.014 |
| Al 27 | N/A | Cs 133 | <0.007 |
| Si 28 | <14 | Ba 137 | <0.056 |
| K 39/41* | <1.4 | La 138/139 | 0.0743 |
| Ca 43/44* | 1.7173 | Ce 140 | 0.0507 |
| Sc 45 | 0.0451 | Pr 141 | 0.0083 |
| Ti 47 | <0.035 | Nd 146 | 0.0264 |
| V 51 | 0.0131 | Sm 147 | 0.0196 |
| Cr 52 | 0.2720 | Eu 153 | 0.0063 |
| Mn 55 | 0.1822 | Gd 157 | 0.0991 |
| Fe 56 | <0.14 | Tb 159 | 0.1991 |
| Co 59 | 0.2041 | Dy 163 | 0.0357 |
| Ni 60 | 0.0978 | Ho 165 | 0.2552 |
| Cu 63 | 0.0660 | Er 166 | 0.1507 |
| Zn 66 | 0.0409 | Tm 169 | 0.1131 |
| Ga 71 | 0.1525 | Yb 171, 2, 3 | 0.1682 |
| Ge 72 | <0.007 | Lu 175 | 0.0133 |
| As 75 | 0.0306 | Hf 178 | 0.0305 |
| Se 78 | <0.035 | Ta 181 | <0.0035 |
| Rb 85 | 0.0526 | W 182 | <0.007 |
| Sr 84/87/88 | 0.3379 | Re 185 | <0.0035 |
| Y 89 | N/A | Ir 193 | <0.035 |
| Zr 90/92/94 | 1.1108 | Pt 195 | <0.056 |
| Nb 93 | <0.007 | Au 197 | 0.0164 |
| Mo 95 | 0.0320 | Tl 205 | 0.0430 |
| Ru 101 | <0.007 | Pb 208 | 0.0094 |
| Rh 103 | <0.042 | Bi 209 | 0.0213 |
| Pd 104, 8, 10 | <0.007 | Th 232 | <0.007 |
| Ag 107/109 | 0.0592 | U 238 | 0.0043 |

The ceramic body assembly may be placed in a furnace for joining according to a variety of thermal profiles as disclosed herein. Fixturing and supports as necessary to maintain contact between the substrates were used during thermal treatment as familiar to one skilled in the art.

The method of making a joined ceramic body disclosed herein comprises step b increasing the temperature of the ceramic body assembly to a sintering temperature of the powder of silicon dioxide sufficient to join first and second ceramic portions to form the joined ceramic body.

In embodiments, sintering of the silicon dioxide powder and/or the joining material as disclosed herein to form the joining layer of the joined ceramic body may be achieved through direct, in situ sintering of the silicon dioxide powder or powder mixture of the joining material. This in situ sintering, which forms the joining layer from the starting oxide powders, preserves the purity of the starting materials thereby transferring them to the joining layer. Known in the art is the process of first forming or fritting a glass or glass ceramic which is thereafter ground into powder form, introducing impurities and contaminants into the glass or glass ceramic and thereby the joining layer. The ceramic body assembly of step b may be heated in a furnace at temperatures and for durations sufficient to sinter the powders comprising the silicon dioxide and/or joining material of step a) into a joining layer to form the joined ceramic body.

Joining or sintering of the ceramic body assembly to form the joined ceramic body may be performed at sintering temperatures of between 1100 to 1500° C., preferably between 1100 to 1400° C., preferably between 1100 to 1300° C., preferably between 1100 to 1200° C., preferably between 1200 to 1500° C. preferably between 1300 to 1500° C., preferably between 1400 to 1500° C., preferably between 1200 to 1400° C. Joining of the ceramic body assembly may be performed at sintering times of between 1 to 8 hours, preferably between 1 to 6 hours, preferably between 1 to 4 hours, preferably between 6 to 8 hours, preferably between 4 to 8 hours, preferably between 3 to 5 hours. Heating rates may be between 1° C./minute and 20° C./minute, between 1° C./minute and 10° C./minute, and cooling rates may be between 0.5° C./minute and 20° C./minute, preferably between 0.75 C/minute and 15° C./minute, preferably between 1° C./minute and 10° C./minute. The sintering process transforms the joining material into the joining layer as disclosed. The ceramic body assemblies were sintered under ambient pressure and atmospheric conditions.

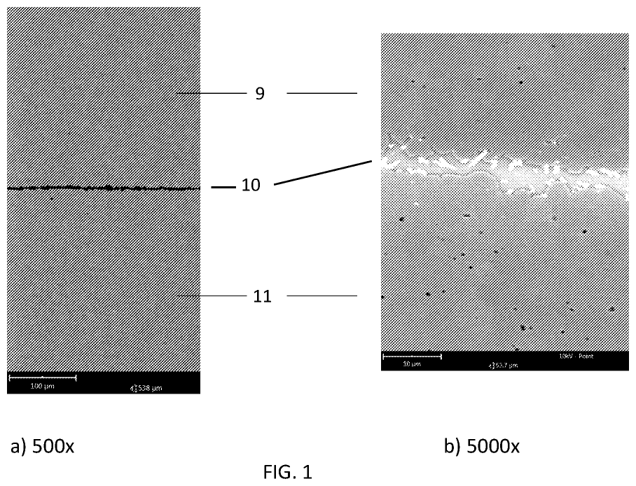

FIG. 1 depicts a joined ceramic body according to an embodiment as disclosed wherein first and second ceramic portions 9 and 11 respectively, may be bonded using a glass or glass ceramic based joining layer 10 comprising combinations of silicon dioxide, aluminum oxide and in embodiments also rare earth oxides such as rare earth oxides selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof. The silicon dioxide and/or the joining material forming the joining layer upon sintering may be dispersed in a suspension medium to form a paste ranging from about 5 volume % to 50 volume %, preferably between 10 and 50% by volume, between 20 and 50% by volume of the paste, preferably between 30 and 50% by volume of the paste. In embodiments, the joining material may have a maximum particle size of 6 um and less. A bond thickness, 12, of from 0.5 to 20 um, preferably from 0.5 to 15 um, preferably from 0.5 to 10 um, preferably from 0.5 to 6 um, preferably from 1 to 15 um, preferably from 3 to 10 um, more preferably from 4 to 8 um, may be achieved, however other bond thicknesses may be contemplated, dependent upon the characteristics of the starting joining materials, such as composition of the joining materials and ceramic portions, particle size distribution and maximum particle or agglomerate size. As depicted in FIGS. 1a and b, no reaction between the ceramic portions 9 & 11 and the joining layer 10 is observed. The joining layer 10 between interfaces of the ceramic portions 9 and 11 does not have a transition area and is uniform in phase distribution throughout the thickness of the joining layer. The joining layer 10 may have a glass or a glass ceramic phase uniformly distributed across the thickness between the ceramic portions, which is free of fluorides or oxyfluorides. A transition area or region as defined herein represents an area or region formed proximal to at least one ceramic portion and within the joining layer, which may be caused by a chemical reaction (between the at least one ceramic portion and the joining layer) to form a region differing in composition, crystalline phase, or other characteristics. Each of the joined ceramic body, joining layer, joining material and plasma resistant composition as disclosed herein are free of fluorides and/or oxyfluorides. Each of the joined ceramic body, joining layer, joining material and plasma resistant composition as disclosed are free of transition areas as defined herein.

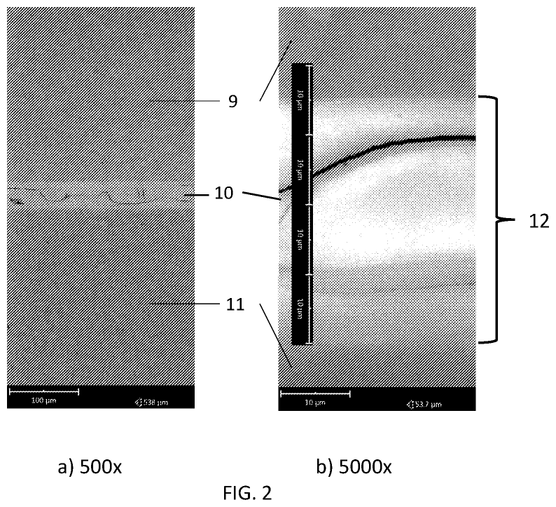

FIG. 2 illustrates a joined ceramic body not according to an embodiment as disclosed wherein ceramic portions comprised of aluminum oxide were bonded at 1400° C. for 4 hours using a glass forming joining material comprising high purity (>99.999%) silicon dioxide granulate (such as Heraeus zandosil G220®) dispersed in a 50 volume % aqueous paste. The granulate is reported to have a d50 particle size of 200 to 250 um. A bond thickness 12 of about 35 um was measured and cracking was observed in the joining layer, 10. The large granulate particle sizes of the silicon dioxide, and significant differences (greater than 10%) in coefficient of thermal expansion between the ceramic portion/s 9, 11 and the joining layer 10 may have resulted in cracking of the joining layer. Tables 2 and 3 list ceramic portions and various joining materials combined to make the joined ceramic bodies as disclosed. In some embodiments, the glass ceramic joining material used to form the joining layer in accordance with Table 3 may be a mixture of powders as disclosed herein comprising about 50% SiO2, about 29% Y2O3 and about 21% Al₂O₃ by weight. Other compositions and ratios of joining materials may be used dependent upon the selection of ceramic portions. In other embodiments, the glass ceramic joining material may be comprised of a powder mixture of about 40% SiO2, about 34% Y2O3 and about 26% Al2O3 by weight. In other embodiments, the joining material comprises silica in amounts of from 25 wt % silica to 99 wt % silica, and the balance comprising a mixture of yttria and alumina in a ratio of 43 wt % alumina and 57 wt % yttria. Table 3 lists exemplary compositions of the joining material comprising yttria, alumina and silica and the conditions for formation of the joined ceramic bodies as disclosed herein.

Properties of the glass joining layer comprising silica are listed in Table 2.

TABLE 2
Glass Joining Layer

| | ceramic | ceramic | Joining | T (Celsius)/t | |
|---|---|---|---|---|---|
| Example | portion 1 | portion 2 | Material | (hours) | Join Result |
| 1 | Al2O3 | Al203 | SiO2 | 1400/4 | Acceptable |
| 2 | Al2O3 | Al203 | SiO2 | 1200/4 | Acceptable |
| 3 | Al2O3 | Al203 | SiO2 | 1000/8 | Unacceptable |
| 5 | Al2O3 | Y203 | SiO2 | 1400/4 | Acceptable |
| 6 | Al2O3 | Al2O3 | Granulated | 1400/4 | Cracking |
| | | | SiO2 | | |
| 7 | Y203 | Y203 | SiO2 | 1400/4 | Acceptable |
| 8 | YAG | YAG | SiO2 | 1400/4 | Acceptable |

TABLE 3
Glass Ceramic Joining Layer

| | ceramic | ceramic | | T (Celsius)/t | |
|---|---|---|---|---|---|
| Example | member 1 | member 2 | Joining Material (wt %) | (hours) | Join Result |
| 1 | Al2O3 | Al203 | 40SiO2/25.8Al2O3/34.2Y2O3 | 1400/4 | Acceptable |
| 2 | Al2O3 | Al203 | 40SiO2/25.8Al2O3/34.2Y2O3 | 1200/4 | Acceptable |
| 3 | Al2O3 | Al203 | 40SiO2/25.8Al2O3/34.2Y2O3 | 1000/8 | Unacceptable |
| 4 | Al2O3 | Y203 | 40SiO2/25.8Al2O3/34.2Y2O3 | 1400/4 | Unacceptable |
| 9 | Al2O3 | Al203 | 50SiO2/21.5Al2O3/28.5Y2O3 | 1400/1 | Acceptable |
| 10 | Al2O3 | Al203 | 50SiO2/21.5Al2O3/28.5Y2O3 | 1500/1 | Acceptable |

As a guide, FIG. 8 is provided to show the ratios required to make joining materials of different compositions comprising yttria, alumina and silicon dioxide. Yttria and alumina are batched in ratios to form the YAG phase, combined with from 25 wt % to 99% silica, and in other embodiments the joining material as disclosed herein may comprise 100% silica (as depicted along the black line of FIG. 8). Typical joining material compositions disclosed herein have alumina and yttria in ratios to form YAG upon sintering (about 43 wt % alumina and about 57 wt % yttria), combined with silica in silica amounts from 25% by weight up to 99% by weight and the balance a mixture of yttria and alumina (batched to form YAG) in combined amounts of from 1 to 75% by total weight of the joining material. In other embodiments as disclosed herein, the joining material may comprise 100% of silicon dioxide.

Although the embodiments and examples as disclosed herein are performed under ambient pressure and do not require use of external pressure, externally applied pressures between 0.01 and 1.4 MPa, preferably between 0.01 and 0.7 MPa, preferably between 0.01 and 0.35 M, preferably between 0.01 and 0.14 MPa, preferably between 0.01 and 0.07 MPa may be used if desired.

In embodiments, the sintering profile may be adjusted to a temperature and time sufficient to permit the formation of a glass ceramic joining layer formed in situ between surfaces of the ceramic substrates from the powder joining mixture. The resultant properties and composition of the glass ceramic joining layer will be determined by the powder mixture composition, substrate material, and thermal profile used during the joining process, in particular the cooling rate to allow for crystallization of the joining material upon cooling. An exemplary cooling rate to minimize thermal stress is from 0.5 C/min to 5 C/min, dependent upon thermal mass/part size.

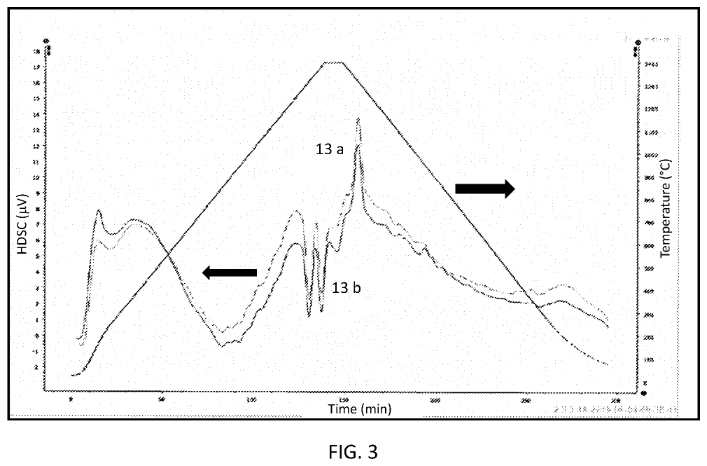

FIG. 3 illustrates differential scanning calorimetry (DSC) results as performed in the art for a joining material comprising powders of yttria, silica and alumina for forming a glass ceramic joining layer according to embodiments as disclosed herein. A Linseis Model DSC PT 1600 was used for all measurements. FIG. 3 shows exothermic crystallization peak 13a which corresponds to in-situ crystallization of at least one crystalline ceramic phase (according to the compositions depicted in the phase diagram of FIG. 8) from the joining material. In some embodiments, the at least one crystalline ceramic phase may be selected from the group consisting of mullite, alumina, Y2Si2O7, Y2SiO5 and Y3Al5O12 (yttrium aluminum garnet, YAG). The YAG phase is preferably polycrystalline. The crystalline ceramic phases are formed through an in situ reactive sintering process from the starting powders of silica, yttria and alumina and dispersed in a glassy silica rich phase or matrix to form a glass ceramic joining material. Endothermic “dips” denoted as 13b in FIG. 3 indicate melting to form at least one glassy, silica rich liquid phase. Without being bound by any particular theory, bonding between the ceramic portions may be achieved by selection of a range of joining material compositions that melt and form silica rich, liquid phases at temperatures compatible with those of the method, whereby the silica rich, liquid phases wet and join surfaces of the ceramic portions during sintering. The compositional range of the joining material which forms by liquid phase sintering (at temperatures compatible with the method as disclosed of from 1100° C. to 1500° C.). are depicted within the dashed region according to FIG. 8, and comprises from 25 to 60 wt % of silica and the balance comprising a mixture of from 25 to 50 wt % alumina and from 50 to 75 wt % of yttria. Across this compositional range, the crystalline ceramic phases of mullite (3Al2O3-2SiO2), Y2Si2O7, alumina (Al2O3), Y3Al5O12 (YAG), and Y2SiO5 and combinations thereof may form. In embodiments, at least one of these phases may be present in combination with a glassy, amorphous silica phase to form a glass ceramic. The yttria, silica, alumina phase diagram according to H. Mao, M. Selleby and M. Fabrichnaya (2008) provides guidance as to the crystalline phases formed from the compositional ranges of the powder mixtures and the plasma resistant compositions as disclosed herein. As such, embodiments of the joining materials may comprise silica in an amount of from 25 to 60% by weight, and the balance comprising a mixture of alumina in amounts of from 25 to 50% by weight, and yttria in amounts of from 50 to 75% by weight. Across this compositional range, at least one of the crystalline ceramic phases of mullite (3Al2O3-2SiO2), Y2Si2O7, alumina (Al2O3), Y3Al5O12 (YAG), and Y2SiO5 and combinations thereof may form dispersed in a glassy, silica rich phase or matrix.

Compositions of the joining material as disclosed herein typically comprise from 25 to 99 wt % silica, and the balance comprising a mixture of from 25 to 50 wt % alumina and from 50 to 75 wt % of yttria. In other embodiments, the joining material may comprise a high purity silica composition formed from a high purity silica nanopowder such as Heraeus zandosil 30 and 30 P®. Across these compositional ranges, bonding between the ceramic portions is achieved through liquid or viscous phase sintering of the joining material, and combinations thereof. As such, no reaction between the joining material and the ceramic portions is observed to occur.

The in-situ crystallization of the at least one ceramic phase, from the joining material during liquid phase sintering, combined with a very high purity silica rich glassy phase, provides a high purity, corrosion resistant joining layer (or bond line) between ceramic members which is resistant to the corrosive and erosive effects of halogen based plasmas as used during semiconductor processing.

Crystallization of the joining material to form a glass ceramic as disclosed herein may be observed (as shown by exothermic peaks 13 a) at temperatures of greater than 1000 and 1400° C., thus sintering temperatures of from 1100° C. to 1500° C. are compatible with the method as disclosed. Two measurements were performed, and consistent results between them are depicted in FIG. 3.

The joining layer may vary in the relative amounts of silica rich, glassy phase (the glassy phase is amorphous as known to those skilled in the art) and crystalline, ceramic phases dependent upon the composition of the joining material, the thermal treatment, in particular the cooling rate, and the presence of additives or dopants. The ceramic phase of the joining layer may contain a rare earth oxide element selected from the group consisting of Y, La, Ce, Pr, Nd, Pm, Sm, Eu, Gd, Tb, Dy, Ho, Er, Tm, Yb and Lu and combinations thereof. For application as joining materials in semiconductor processing chambers, very high purity materials are required. Advantageously, use of the joining material as disclosed results in a high purity, alkali and/or alkaline earth free glass or glass ceramic composition with high join strength which is resistant to halogen based plasmas. In embodiments, dopants may be used to enhance specific properties such as viscosity of the glass ceramic during sintering, electrical resistivity, coefficient of thermal expansion, degree of crystallinity in the glass ceramic, and others. The high purity bonding material compositions as disclosed herein may result in similar or improved etch performance beyond that of commercially available structures in use as semiconductor processing chamber components.

The method as disclosed herein comprises step c lowering the temperature of the joined ceramic body. The relative amounts of the amorphous and crystalline phases present in the glass ceramic joining layer may be affected by the cooling rate during lowering the temperature of the joined ceramic body. Crystallization is a time dependent process whereby higher cooling rates reduce the amount of time for crystallization to occur and thus may result in a lower amount of crystalline phase and a correspondingly higher amount of amorphous phase in the glass ceramic joining layer. Accordingly, lower cooling rates may increase the amount of time for crystallization to occur and thus may result in a greater amount of crystalline phase and may result in a correspondingly lower amount of amorphous phase in the glass ceramic joining layer. The thermal treatment as disclosed herein may be modified to influence the amount of crystalline phase present in the glass ceramic joining layer. The amount of amorphous and crystalline phases may also be affected by other variables such as joining material composition and particle size distribution, presence of dopants, purity levels in the starting materials, among others. Cooling rates of between 0.5° C./minute and 20° C./minute, preferably between 0.75 C/minute and 15° C./minute, preferably between 1° C./minute and 10° C./minute may be used. Cooling may be performed under ambient conditions or in embodiments under forced convection.

The method as disclosed herein optionally further comprises step d) machining the joined ceramic body to create a joined ceramic body component for use in a semiconductor processing chamber. Machining may be performed as known to those skilled in the art to form a joined ceramics body component from the joined ceramic body as disclosed herein. Examples of these may be selected from the group consisting of a dielectric window or RF window, a ring, a nozzle or a gas injector, a shower head, a gas distribution plate, an etch chamber liner, a plasma source adapter, a gas inlet adapter, a diffuser, an electronic wafer chuck, a chuck, a puck, an ion suppressor element, a faceplate, and/or a protective ring in etch chambers. Use of the ceramic portions, compound oxide powders, joining materials and methods as disclosed herein may be particularly suited for the preparation of large joined ceramic bodies, for example of diameters between 100 to 622 mm as necessary for use in state of the art semiconductor processing chambers. For example, in one embodiment, the joined ceramic body may be formed in a disk shape having a diameter from 100 mm to 622 mm in diameter and across a range of thicknesses, from 5 mm to 60 mm. In another embodiment, the joined ceramic body may be formed in a disk shape having a diameter from 100 mm to 622 mm in diameter. In another embodiment, the joined ceramic body may be formed in a disk shape having a diameter from 100 mm to 406 mm in diameter. In other embodiments, the joined ceramic body may have a size of from 200 mm to 622 mm, preferably from 300 to 622 mm, preferably from 350 to 622 mm, preferably from 400 to 622 mm, more preferably from 450 to 622 mm, more preferably from 500 to 622 mm, more preferably 550 to 622 mm, each with regard to a longest dimension of the joined body. In embodiments where the joined ceramic body is formed in a disk shape, the longest extension comprises the diameter.

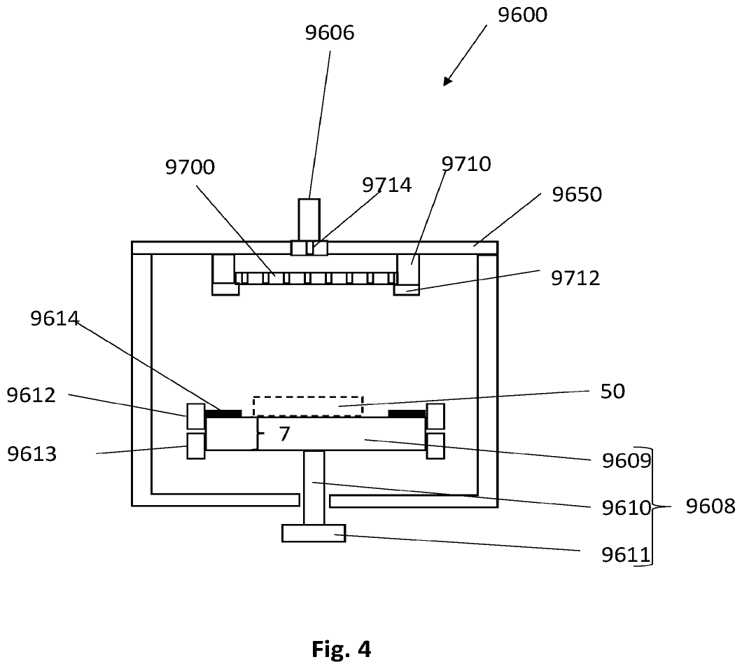

As shown in FIG. 4, another embodiment of the technology as disclosed herein may include a semiconductor processing system 9600, also called processing system. Processing system 9600 comprises a vacuum chamber 9650, a vacuum source, and a chuck 9608 on which a wafer 50, also denoted as semiconductor substrate, is supported. A showerhead 9700 forms an upper wall or is mounted beneath an upper wall of the vacuum chamber 9650. The ceramic showerhead 9700 includes a gas plenum in fluid communication with a plurality of showerhead gas outlets for supplying process gas to the interior of the vacuum chamber 9650. The showerhead 9700 is in fluid communication with a gas delivery system 9606. Furthermore, the showerhead 9700 may comprise a central opening configured to receive a central gas injector (also referred to as nozzle), 9714. An RF energy source energizes the process gas into a plasma state to process the semiconductor substrate. The flow rate of the process gas supplied by the central gas injector 9714 and the flow rate of the process gas supplied by the ceramic showerhead can be independently controlled. The showerhead 9700, the gas delivery system 9606 and the central gas injector 9714 may be made from the joined ceramic body as disclosed herein.

System 9600 may further include an electrostatic chuck 9608 that is designed to carry a wafer 50. The chuck 9608 may comprise a puck 9609, for supporting the wafer 50. The puck 9609 may be formed from the joined ceramic body as disclosed herein and may have a chucking electrode disposed within the puck proximate a support surface of the puck 9609 to electrostatically retain the wafer 50 when disposed on the puck 9609. The chuck 9608 may comprise a base 9611 having a ring-like extending to support the puck 9609; and a shaft 9610 disposed between the base and the puck to support the puck above the base such that a gap is formed between the puck 9609 and the base 9610, wherein the shaft 9610 supports the puck proximate a peripheral edge of the puck 9609. Chuck 9608 and puck 9609 may be made from the joined ceramic body as disclosed herein.

Parts of the surface of the showerhead 9700 may be covered with a shield ring 9712. Parts of the surface of the showerhead 9700, especially radial sides of the surface of the showerhead 9700 may be covered with an upper shield ring 9710. Shield ring 9712 and upper shield ring 9710 may be made from the joined ceramic body as disclosed herein.

Parts of the supporting surface of the puck 9609 may be covered with a cover ring 9614. Further parts of the surface of the puck 9609 may be covered with a top shield ring 9612 and/or a shield ring 9613. Shield ring 9613, cover ring 9614 and top shield ring 9612 may be made from the joined ceramic body as disclosed herein.

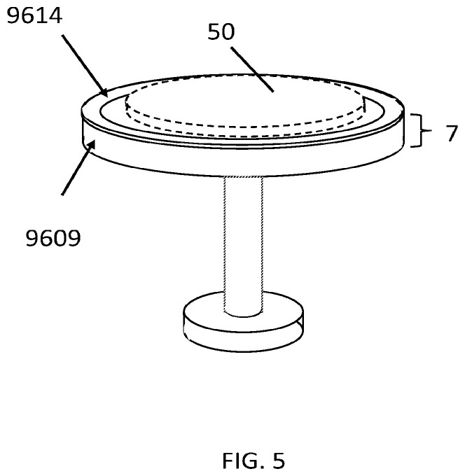

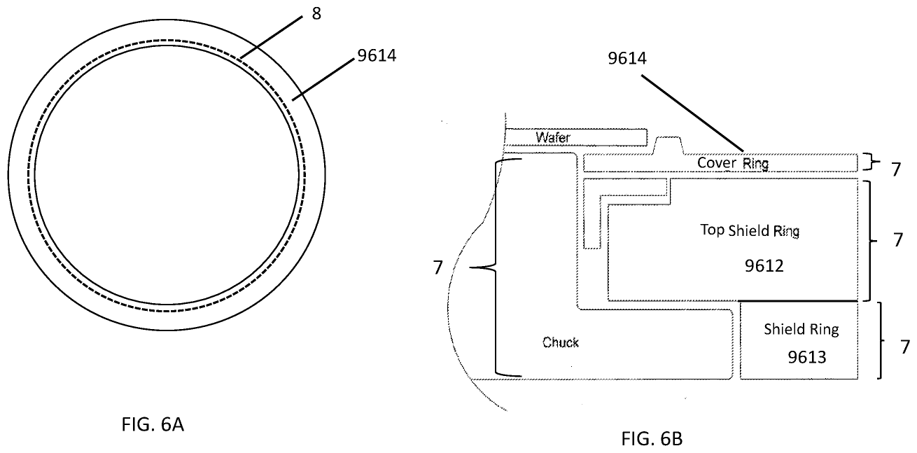

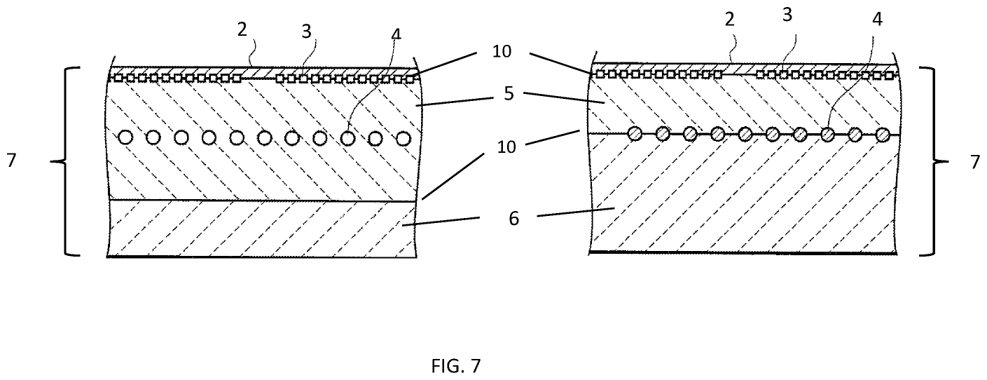

Depicted in FIG. 5 is a wafer support assembly comprising a puck 9609 which may be at least part of an electronic wafer chuck or electrostatic chuck (ESC), and cover ring 9614 each of which may have embedded features such as wires, traces, mesh, a coil shape, a sheet, a screen, etc. in a cross section 7 as depicted in FIGS. 6A, 6B and FIG. 7.

FIG. 6A illustrates a plan view of a cover ring 9614 formed from the joined ceramic body as disclosed with an embedded element 8 which may be a wire, a trace, a mesh, a screen, a coil shape, a screen, and the like. Other configurations and embodiments of embedded element 8 are within the scope of the disclosure. FIG. 6B shows a cross section view of cover ring 9614, top shield ring 9612 and shield ring 9613 which may be formed from the joined ceramic body as disclosed and having embedded or laminated elements as depicted in FIG. 7.

FIG. 7 illustrates a cross section view of an exemplary joined ceramic body having a top layer 2 which may be a dielectric layer; electrodes 3 which may be embedded metal or resistive features made for example of tungsten, platinum, molybdenum or niobium, or other refractory, precious metals; resistive element 4 which may be made from materials having a resistivity and other properties such as dielectric loss selected for compatibility with ceramic portions 5 and 6, for example when ceramic portions 5 and 6 are aluminum oxide, resistive element 4 may be refractory or precious metals such as niobium, tungsten, molybdenum or platinum; wherein elements 3 and 4 may be configured according to application specific requirements, and ceramic region 5 and ceramic region 6 may comprise any number of ceramic portions as disclosed herein and combinations thereof. In preferred embodiments, either of ceramic regions 5 and/or 6 comprise aluminum oxide and/or YAG. For example, resistive element 4 may be disposed in a 2D or 3D configuration such that it may provide control of heating across a volume of the ceramic portions 5 or 6. The electrodes 3 and/or resistive elements 4 may be formed atop the ceramic portions by screen printing, stencil printing, jet deposition, and other methods as known to those skilled in the art. The joining layer 10 formed by the materials and methods as disclosed herein may be disposed between ceramic portions 5 and 6, also between the ceramic portions and electrodes 3 and resistive elements 4, and combinations thereof to provide a plasma resistant bond to form the joined ceramic component from at least two ceramic portions, without limitation. In preferred embodiments, the joining layer 10 is contiguous with ceramic portions 5 and 6.

Properties of the joined ceramic body component, such as corrosion and erosion resistance, coefficient of thermal expansion, thermal conductivity, and dielectric breakdown strength among others may be determined at least in part by the materials selected for use forming the joining layer. Use of highly pure silicon dioxide and the joining materials as disclosed herein forms a glass or a glass ceramic joining layer which provides a high strength bond between ceramic portions while maintaining resistance to halogen based plasmas. The aforementioned properties of the joined ceramic body and/or component may also be affected by the thickness of the joining layer. Minimizing the thickness of this layer may provide increased resistance to plasma erosion and corrosion during use and decrease stress within the layer. Therefore, it is desirable to have a bond thickness that is, for example, between 0.5 and 20 um in thickness, between 0.5 and 15 um in thickness, between 0.5 and 10 um in thickness, between 0.5 and 6 um in thickness, preferably from 1 to 15 um in thickness, preferably from 3 to 10 um in thickness, more preferably from 4 to 8 um in thickness. The joining layer enables the fabrication of ceramic bodies and components from a wide range of materials capable of supporting greater design complexity. As example, FIG. 5 depicts a wafer support assembly having a puck, 9609 which may be a part of a chuck or electronic wafer chuck or electrostatic chuck (ESC), and a cover ring 9614. The puck and/or cover ring may have multiple layers and embedded materials as illustrated in the cross section 7 of FIG. 7.

### Exemplary Embodiments

For all examples, high purity silicon dioxide nanopowder was used, such as Heraeus Zandosil® 30 and zandosil 30P®. All examples were performed at ambient pressure.

For examples 1 to 4, the joining material selected for evaluation contained compound oxides by weight of 50% silicon dioxide, 21.5% aluminum oxide and 28.5% yttrium oxide. For examples 1 through 5, 7 and 9, high purity silicon dioxide as disclosed herein was used to bond the ceramic portions. Examples 1 to 4 are exemplary of bonding ceramic portions using the compound oxide powders and the silica powder as disclosed. All starting powders are of purity at least 99.99% and greater, and free of fluorides and oxyfluorides. Properties of the starting oxides are listed in Table 1. According to embodiments of the examples, a joining layer comprising pure silica (formed from the silica nanopowder) forms an amorphous, glassy phase as known to those skilled in the art.

The joining materials as disclosed were dispersed at 40% to 50% solids loading in an aqueous suspending medium. Samples were sintered at varying temperatures and times as disclosed following. Across all embodiments as disclosed herein, no transition areas were observed. A transition area or region as defined herein represents an area or region formed proximal to at least one ceramic portion and between interfaces of the ceramic portions within the joining layer by a chemical reaction between the two to form a region differing in composition, crystalline phase, or other characteristics.

Example 1: A joined ceramic body was formed from a joining material comprising aluminum oxide, yttrium oxide and silicon dioxide each having purity, particle size distribution and surface area as disclosed herein (see Table 1), prepared in a 40 volume percent aqueous paste, ball milled using high purity (>99.99%) alumina media, and disposed between ceramic portions made of aluminum oxide having a purity of at least 99.99% and higher to form a ceramic body assembly. The composition of the joining material is as disclosed in Table 3. The ceramic body assembly was sintered at a sintering temperature of 1400° C. for 4 hours under ambient pressure in air to form a joined ceramic body. The joining material formed a glass ceramic upon in-situ, reactive sintering as depicted in accordance with DSC results of FIG. 3 (as measured according to ASTM D3418). The glass ceramic comprised at least one crystalline ceramic phase selected from the group consisting of mullite, alumina, Y2Si2O7, Y2SiO5, Y3Al5O12 (yttrium aluminum garnet, or YAG) (according to the phase diagram of H. Mao, M. Selleby and M. Fabrichnaya (2008)), wherein the crystalline ceramic phase is dispersed in a glassy amorphous matrix comprising silica. The joining layer had a bond thickness of between 2 to 5 um, and acceptable bonding between the ceramic portions was achieved (i.e., an integral body was achieved after sintering). The joining layer was observed to be uniform across a thickness between the ceramic portions, and without cracking or fissures. This is depicted in FIG. 1 a) at 500× magnification, and b) at 5000× magnification. As evidenced by FIGS. 1a and b, no reaction between the ceramic portions and the joining material was observed. The joining layer formed between interfaces of the aluminum oxide portions does not have a transition area and is uniform in phase distribution throughout. The joining layer comprised a glass ceramic which is free of fluorides and/or oxyfluorides. As such, disclosed herein is a joined ceramic body which is free of, or substantially free of, fluorides and/or oxyfluorides. In alternate embodiments, acceptable bonding between the ceramic portions was also achieved when a nanopowder of silicon dioxide powder having the surface area, purity and particle size characteristics as disclosed in Example 5 was disposed between the ceramic portions and sintered in accordance with this example.

Example 2: A joined ceramic body was formed from the glass ceramic joining material as disclosed in Example 1, disposed between surfaces of ceramic portions made of aluminum oxide as in Example 1 to form a ceramic body assembly. The ceramic body assembly was sintered at 1200° C. for 4 hours under ambient pressure in air to form a joined ceramic body. A glass ceramic joining layer was formed comprising the phases as disclosed in accordance with Example 1. Acceptable bonding between the ceramic portions was achieved using the joining material as disclosed herein. In alternate embodiments, acceptable bonding between the ceramic portions was also achieved when a nanopowder of silicon dioxide having the surface area, purity and particle size characteristics as disclosed herein was disposed between the ceramic portions and sintered in accordance with this example.

Example 3: A joined ceramic body was formed from the glass ceramic joining material as disclosed in Example 1, disposed between ceramic portions made of aluminum oxide as disclosed in Example 1 to form a ceramic body assembly. The ceramic body assembly was sintered at 1000° C. for 8 hours under ambient pressure in air to form a joined ceramic body. Detachment of the ceramic sintered body was observed due to insufficient bonding between the ceramic portions and the joining material. Detachment of the ceramic sintered body was also observed when silicon dioxide powder having the surface area, purity and particle size characteristics as disclosed herein was disposed between the ceramic portions due to insufficient bonding between the ceramic portions and the joining material. The temperature of 1000° C. was too low for proper joining and detachment of the body was observed.

Example 4: A joined ceramic body was formed from the joining material as disclosed in Example 1, disposed between ceramic portions made of aluminum oxide and yttrium oxide, each having a purity of at least 99.99% and greater to form a ceramic body assembly. The ceramic body assembly was sintered at 1400° C. for 4 hours under ambient pressure in air to form a joined ceramic body. Detachment of the ceramic sintered body was observed at the yttria/joining material interface due to insufficient bonding between the yttria ceramic portion and the joining material.

Example 5: A joined ceramic body was formed from silicon dioxide nanopowder having a purity of at least 99.999% and higher, a surface area of between 25 and 40 m2/g, and an average particle size of between 20 to 200 nm as disclosed herein. The powder was dispersed in an aqueous suspending medium at about 50% loading by volume and disposed between ceramic portions made of aluminum oxide and yttrium oxide, each having a purity of at least 99.99% and greater to form a ceramic body assembly. The ceramic body assembly was sintered at 1400° C. for 4 hours under ambient pressure in air to form the joined ceramic body. Acceptable bonding between the ceramic portions was achieved using the silicon dioxide powder as disclosed herein.

Example 6: A joined ceramic body not in accordance with the materials and methods as disclosed was made of aluminum oxide ceramic portions having purity of at least 99.99% and greater to form a ceramic body assembly. In this example, high purity (>99.999%) granulated SiO2 powder (such as Heraeus zandosil G220®), having an average (d50) agglomerate size of from 200 to 250 um was used to form the joining layer. The silica granulate was dispersed in a 50 volume % aqueous paste. The ceramic body assembly was sintered at 1400° C. for 4 hours under ambient pressure in air to form a joined ceramic body. A bond thickness of 35 um resulted, as depicted in FIG. 2 a) at a 500× magnification, and 2 b) at 5000× magnification. Although bonding occurred between the ceramic portions and the silicon dioxide layer, significant cracking was observed within the joining layer. Greater stresses may be placed upon this thicker, predominately or fully glass bond layer dependent upon the thermal expansion characteristics of the ceramic portions, exacerbating the observed cracking. Finer particle size of the silica powder (such as typical of nanopowders), as well as a reduced bond thickness (less than 35 um) may increase the strength of the joining layer, thus mitigating the observed cracking.

Example 7: A joined ceramic body was formed from silicon dioxide powder having a purity of at least 99.999% and higher, a surface area of between 25 and 40 m2/g, and an average particle size of between 20 to 200 nm as disclosed herein was disposed between ceramic portions made of yttrium oxide having a purity of at least 99.99% and greater to form a ceramic body assembly. The ceramic body assembly was sintered at 1400° C. for 4 hours under ambient pressure in air to form the joined ceramic body. Acceptable bonding between the yttria ceramic portions was achieved using the silicon dioxide powder as disclosed herein.

Example 8: A joined ceramic body was formed from silicon dioxide nanopowder powder having a purity of at least 99.999% and higher, a surface area of between 25 and 50 m2/g (as measured by BET), and an average particle size of between 20 to 200 nm as disclosed herein was disposed between ceramic portions made of yttrium aluminum oxide, garnet structure (YAG, Y3Al5O12), having a purity of at least 99.99% and greater to form a ceramic body assembly. The ceramic body assembly was sintered at 1400° C. for 4 hours under ambient pressure in air to form the joined ceramic body. Acceptable bonding between the ceramic portions was achieved using the silicon dioxide powder as disclosed herein.

Tables 2 and 3 summarize the joined ceramic bodies according to embodiments as disclosed herein.

### Reference Number Listing

| | Reference | |
|---|---|---|
| FIG./S | Number | Description |
| 7 | 2 | top layer |
| 7 | 3 | electrode |
| 7 | 4 | resistive element |
| 7 | 5 | ceramic portion |
| 7 | 6 | ceramic portion |
| 4, 5, 6B, 7 | 7 | cross section |
| 6A | 8 | embedded element |
| 1, 2 | 9, 11 | ceramic portion/s |
| 1, 2 | 10 | joining layer |
| 1, 2 | 12 | bond thickness |
| 3 | 13 | exothermic peaks |
| 4, 5 | 50 | wafer |
| 4 | 9600 | semiconductor processing system |
| 4 | 9606 | gas delivery system |
| 4 | 9608 | chuck |
| 4, 5 | 9609 | puck |
| 4 | 9610 | shaft |
| 4 | 9611 | base |
| 4, 6B | 9612 | top shield ring |
| 4, 6B | 9613 | shield ring |
| 4, 5, 6A, 6B | 9614 | cover ring |
| 4 | 9700 | showerhead |
| 4 | 9710 | upper shield ring |
| 4 | 9712 | shield ring |
| 4 | 9714 | central gas injector |
| 4 | 9650 | vacuum chamber |

Example 9: A joined ceramic body was formed from a joining material comprising 50 wt % silica, 21.5 wt % alumina and 28.5 wt % yttria. The silica, alumina and yttria had the powder properties as disclosed in accordance with Table 1. The joining material had a purity of at least 99.99% and higher and was dispersed in water in an amount of about 40 wt % solids to form a paste and disposed between ceramic portions made of aluminum oxide having a purity of at least 99.99% and greater, to form a ceramic body assembly. The ceramic body assembly was sintered at 1400° C. for 1 hour under ambient pressure in air to form a joined ceramic body. Upon sintering, a glass ceramic joining layer having a thickness of about 10 um was formed by an in-situ sintering reaction to form a glass ceramic comprising a glassy, amorphous silica rich phase and at least one crystalline ceramic phase in accordance with the phases disclosed in Example 1. Acceptable bonding between the alumina ceramic portions was achieved.

Example 10: A joined ceramic body was formed from a joining material comprising 50 wt % silica, 21.5 wt % alumina and 28.5 wt % yttria. The silica, alumina and yttria had the properties as disclosed in accordance with Table 1. The joining material had a purity of at least 99.99% and higher and was dispersed in water in an amount of about 50 wt % solids and disposed between ceramic portions made of aluminum oxide having a purity of at least 99.99% and greater, to form a ceramic body assembly. The ceramic body assembly was sintered at 1500° C. for 1 hour under ambient pressure in air to form the joined ceramic body. Upon sintering, a glass ceramic joining layer having a thickness of from 5 to 10 um was formed by an in-situ reaction to form a glassy, amorphous silica rich phase and at least one crystalline ceramic phase in accordance with Example 1. Acceptable bonding between the alumina ceramic portions was achieved.

A number of embodiments of the invention have been disclosed. Nevertheless, it will be understood that various modifications may be made without departing from the spirit and scope of the invention. Accordingly, other embodiments are within the scope of the following claims.

1. A joined ceramic body, comprising:
a. a first ceramic portion comprising a first ceramic;
b. a second ceramic portion comprising a second ceramic;
c. a joining layer formed between the first ceramic portion and the second ceramic portion, wherein the joining layer has a bond thickness of from 0.5 to 20 um and comprises silicon dioxide having a total impurity content of 20 ppm and less relative to a mass of the joining layer.

2. The joined ceramic body of claim 1 wherein the joining layer comprises an amorphous glassy phase having a total impurity content of 10 ppm and less relative to a mass of the joining layer.

3. The joined ceramic body of claim 1 wherein the joining layer comprises a glass ceramic comprising an amorphous glassy phase and at least one crystalline ceramic phase.

4. The joined ceramic body of claim 1 wherein the joining layer comprises at least one crystalline ceramic phase having crystallinity in an amount of from 5% to 99% by volume of the joining layer.

5. The joined ceramic body of claim 1 wherein the joining layer comprises at least one crystalline ceramic phase having crystallinity in an amount of from 5% to 90% by volume of the joining layer.

6. The joined ceramic body of claim 1 wherein the joining layer comprises at least one crystalline ceramic phase having crystallinity in an amount of from 5% to 70% by volume of the joining layer.

7. The joined ceramic body of claim 1 wherein the joining layer comprises at least one crystalline ceramic phase having crystallinity in an amount of from 10% to 60% by volume of the joining layer.

8. The joined ceramic body of claim 1 wherein the joining layer comprises at least one crystalline ceramic phase having crystallinity in an amount of from 10% to 50% by volume of the joining layer.

9. The joined ceramic body of claim 1 wherein the at least one crystalline ceramic phase comprises at least one selected from the group consisting of mullite, alumina, Y2Si2O7, Y2SiO5 and Y3Al5O12 (yttrium aluminum garnet).

10. The joined ceramic body of claim 1 wherein the Y3Al5O12 (yttrium aluminum garnet) is polycrystalline.

11. The joined ceramic body of claim 1 wherein the joining layer has a total impurity content of 10 ppm and less relative to a mass of the joining layer.

12. The joined ceramic body of claim 1 wherein the joining layer has a total impurity content of 5 ppm and less relative to a mass of the joining layer.

13. The joined ceramic body of claim 1 wherein the joining layer has a total purity of 99.99% and higher relative to 100% purity.

14. The joined ceramic body of claim 1 wherein the joining layer has a total purity of 99.995% and higher relative to 100% purity.

15. The joined ceramic body of claim 1 wherein the joining layer has a total purity of 99.999% and higher relative to 100% purity.

16. The joined ceramic body of claim 1 wherein the joining layer has a total alkali or alkali earth element content of 5 ppm and less relative to a mass of the joining layer.

17. The joined ceramic body of claim 1 wherein the joining layer has a bond thickness of from 1 to 15 um.

18. The joined ceramic body of claim 1 wherein the joining layer has a bond thickness of from 3 to 10 um.

19. The joined ceramic body of claim 1 wherein the joining layer has a bond thickness of from 4 to 8 um.

20. The joined ceramic body of claim 1 wherein the joining layer further comprises a rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof having a purity of 99.99% and higher relative to 100% purity of the joining layer.

21. The joined ceramic body of claim 1 wherein the joining layer further comprises an element selected from the group consisting of Y, La, Ce, Pr, Nd, Pm, Sm, Eu, Gd, Tb, Dy, Ho, Er, Tm, Yb and Lu and combinations thereof.

22. The joined ceramic body of claim 1 wherein the first and second ceramic portions comprises the same ceramic.

23. The joined ceramic body of claim 1 wherein the first and second ceramic comprises different ceramics.

24. The joined ceramic body of claim 1 wherein each of the first and second ceramic portions are selected from the group consisting of aluminum oxide, yttrium oxide, aluminum nitride, yttrium aluminum garnet (YAG; Y₃Al₅O₁₂), silicon carbide, quartz, mullite, SiAlON materials, and combinations thereof.

25. The joined ceramic body of claim 1 wherein the first and second ceramic portions are aluminum oxide.

26. The joined ceramic body of claim 1 wherein the joining layer has a coefficient of thermal expansion (CTE) of from 0 to 10% of each of the first and second ceramic portions.

27. The joined ceramic body of claim 1 wherein the joining layer has a coefficient of thermal expansion (CTE) of from 0 to 5% of each of the first and second ceramic portions.

28. The joined ceramic body of claim 1 wherein the first and second ceramic portions have a purity of 99.99% and higher relative to 100% purity.

29. The joined ceramic body of claim 1 wherein the first and second ceramic portions have a purity of 99.995% and higher relative to 100% purity.

30. The joined ceramic body of claim 1 having a purity of 99.99% and higher relative to 100% purity.

31. A method of making a joined ceramic body, the method comprising:
a. disposing a powder of silicon dioxide between surfaces of a first ceramic portion and a second ceramic portion to form a ceramic body assembly;
b. increasing the temperature of the ceramic body assembly to a sintering temperature sufficient to join first and second ceramic portions to form the joined ceramic body; and
c. lowering the temperature of the joined ceramic body,
wherein the silicon dioxide has a specific surface area of from 25 m²/g to 50 m²/g as measured according to ASTM C1274, and a purity of 99.999% and higher relative to 100% purity, wherein the process is carried out under condition to prepare a joined ceramic body having characteristics as disclosed in claim 1.

32. The method according to claim 31 wherein step a. further comprises a powder of aluminum oxide wherein the aluminum oxide has a purity of 99.99% and higher.

33. The method according to claim 31 wherein step a. further comprises a powder of at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof having a purity of 99.99% and higher.

34. The method according to claim 31 wherein the sintering temperature of step b. is between 1100 and 1500° C.

35. The method according to claim 31 wherein step a. further comprises a powder of yttrium oxide having a purity of 99.995% and greater relative to 100% purity.

36. The method according to claim 31 further comprising the step of:
d. machining the joined ceramic body to create a joined ceramic body component for use in a semiconductor processing chamber.

37. The method according to claim 31 wherein the joined ceramic body component is selected from the group consisting of: a dielectric window or RF window, a ring, a nozzle or a gas injector, a shower head, a gas distribution plate, an etch chamber liner, a plasma source adapter, a gas inlet adapter, a diffuser, an electronic wafer chuck, a chuck, a puck, an ion suppressor element, a faceplate, and/or a protective ring in etch chambers.

38. A joined ceramic body for production of semiconductor chamber components made by the process of claim 31.

39. A joined ceramic body according to claim 31 having a size of from 100 mm to 622 mm, preferably from 200 to 622 mm, preferably from 300 to 622 mm, preferably from 400 to 622 mm, more preferably from 450 to 622 mm, more preferably from 500 to 622 mm, more preferably 550 to 622 mm, each with regard to the longest extension of the ceramic body.

40. A plasma resistant composition comprising:
a. silicon dioxide having a particle size of between 30 and 200 nm and a specific surface area as measured by BET methods of between 25 m2/g and 50 m2/g;
b. aluminum oxide; and
c. at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof; and
d. a suspension medium,
wherein the plasma resistant composition comprises a paste.

41. The plasma resistant composition of claim 40 wherein the silicon dioxide has a total purity of at least 99.999% and higher relative to 100% purity.

42. The plasma resistant composition of claim 40 wherein the at least one rare earth oxide comprises yttrium oxide having a purity of 99.99% and greater relative to 100% purity.

43. The plasma resistant composition of claim 40 having a total purity of at least 99.995% and greater relative to 100% purity.

44. The plasma resistant composition of claim 40 wherein the suspension medium comprises a liquid selected from the group consisting of water, ethanol, isopropanol, glycerol, and combinations thereof.

45. The plasma resistant composition of claim 40 having a maximum particle size (d100) of from 4 to 6 microns.

46. The plasma resistant composition of claim 40 wherein the aluminum oxide has a purity of 99.99% and higher relative to 100% purity.

47. The plasma resistant composition of claim 40 wherein the at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof has a purity of 99.99% and higher.

48. The plasma resistant composition of claim 40 comprising silicon dioxide in an amount of from 25 to 60% by weight, and the balance comprises a mixture of aluminum oxide in an amount of from 25 to 50% by weight, and at least one rare earth oxide in an amount of from 50 to 75% by weight.

49. The plasma resistant composition of claim 48 wherein the rare earth oxide comprises yttrium oxide.

50. The plasma resistant composition of claim 49 having plasma resistant composition comprising:
a. silicon dioxide having a particle size of between 30 and 200 nm and a specific surface area as measured by BET methods of between 25 m2/g and 50 m2/g;
b. aluminum oxide; and
c. at least one rare earth oxide selected from the group consisting of Y2O3, La2O3, CeO2, Nd2O3, Pm2O3, Sm2O3, Eu2O3, Gd2O3, Tb4O7, Dy2O3, Ho2O3, Er2O3, Tm2O3, Yb2O3, Lu2O3 and combinations thereof; and
d. a suspension medium,
wherein the plasma resistant composition comprises a paste.

51. A joined ceramic body comprising:
a. first and second ceramic portions of aluminum oxide;
b. a joining layer formed between the first and second ceramic portions having a bond thickness of from 0.5 to 20 um,
wherein the first and second ceramic portions have a purity of 99.99% and higher, wherein the joining layer comprises a glass ceramic comprising an amorphous glassy phase and at least one crystalline ceramic phase wherein the joining layer has a total impurity content of 20 ppm and less relative to a mass of the joining layer.

52. A joined ceramic body comprising:
a. first and second ceramic portions of yttrium aluminum oxide garnet (YAG, Y3Al5O12);
b. a joining layer formed between the first and second ceramic portions,
wherein the first and second ceramic portions have a purity of 99.99% and higher, wherein the joining layer comprises a glass ceramic comprising an amorphous glassy phase and at least one crystalline ceramic phase wherein the joining layer has a total impurity content of 20 ppm and less relative to a mass of the joining layer and a bond thickness of from 0.5 to 20 um.

53. A joined ceramic body, comprising:
a. first and second ceramic portions of aluminum oxide;
b. a joining layer formed between the first and second ceramic portions,
wherein the first and second ceramic portions have a purity of 99.99% and higher and the joining layer comprises a glass ceramic comprising an amorphous glassy phase and at least one crystalline ceramic phase selected from the group consisting of mullite, alumina, Y2Si2O7, Y2SiO5, and Y3Al5O12 (yttrium aluminum garnet), wherein the joining layer has a total impurity content of 20 ppm and less and a bond thickness of between 0.5 and 20 um.

54. A joined ceramic body comprising:
a. first and second ceramic portions of yttrium aluminum oxide garnet (YAG, Y3Al5O12);
b. a joining layer formed between the first and second ceramic portions, wherein the first and second ceramic portions have a purity of 99.99% and higher, wherein the joining layer comprises a glass ceramic comprising an amorphous glassy phase and at least one crystalline ceramic phase selected from the group consisting of mullite, alumina, Y2Si2O7, Y2SiO5, and Y3Al5O12 (yttrium aluminum garnet), wherein the joining layer has a total impurity content of 20 ppm and less relative to a mass of the joining layer and a bond thickness of from 0.5 to 20 um.
